(19) United States
(12) Patent Application Publication
(10) Pub. No.: US 2013/0056046 A1
(43) Pub. Date: Mar. 7, 2013

(54) Concentrating hybrid solar thermal and photovoltaic collector

(71) Applicant: Feng Shi, Klamath Falls, OR (US)

(72) Inventor: Feng Shi, Klamath Falls, OR (US)

(21) Appl. No.: 13/137,662

(22) Filed: Sep. 1, 2011

(51) Int. Cl. H01L 31/058

(52) U.S. Cl. 136/248

(57) ABSTRACT

A concentrating hybrid solar thermal and photovoltaic collector comprises a close structure concentrator and a vacuum tube hybrid solar thermal and photovoltaic converter to generate electricity and high temperature heat in the mean time. The close structure of concentrator makes it possible to manufacture concentrator with thin and light-weight materials and get rid of support and fastening materials of conventional open concentrator, but still retain strong mechanical strength to against wind load. This structure enables the significant cost and weight reduction. This structure is also able to increase the optical efficiency relative to open system and provides natural protection to relative surface of the concentrator. This structure protects the thermal and photovoltaic converter from any contaminations. The configuration of this concentrator package significantly raises the total efficiency of the device and output high quality heat that makes soar cooling, heating and thermal power generation cost-effective and practical.

### TECHNICAL FIELD

The present disclosure relates generally to solar collector. More specifically, to close structure concentrating hybrid solar thermal and photovoltaic collector.

### BACKGROUND

Solar radiation is a diffuse energy resource. Average solar radiation intensity on earth is around 800 W/m², varying with location, weather and season. The low energy current density of solar radiation causes high cost of solar system due to the expensive large area collectors that is necessary to construct the system. Solar radiation is featured in broad band spectrum and the photon flux of sunlight incident on photovoltaic converters spreads out of a wide energy range from 0.5 to 4 eV. When the broad energy band photons incident on photovoltaic cells, only a small fraction of optical energy is converted into electricity, while the majority of the incident energy is converted into heat. The spectral nature of solar radiation causes low conversion efficiency of photovoltaic system. One of the main approaches to reduce cost of solar system is to replace the flat plate solar collector that collects and converts solar radiation directly with solar concentrator. One of the main approaches used to raise conversion efficiency is to adopt hybrid solar thermal and photovoltaic mechanism to convert the collected sunlight into electricity and heat in the mean time. This approach harvests the heat generated in photovoltaic conversion process, which is usually wasted as energy loss, to realize high total conversion efficiency.

Solar concentrator used for condensing solar radiation has great potential in realizing extremely low cost solar collection. However, the most current solar concentrators are relatively expensive. Generally there are two types of solar concentrator: one is Fresnel Lens (FS) based on refraction of light, and the other is parabolic reflector based on reflection of light. In most of the large scale solar energy application systems, reflective solar concentrators are adopted to collect and condense solar radiation. Most reflective solar concentrators are designed into a concave reflector structure which is generally in either a parabola form or a parabolic trough form. Most, and probably near all, of these reflectors are open systems which have been built of rigid reflective components that are molded and assembled into a predetermined geometric shape and retained by fastening means. In order to protect against wind and load, the rigid reflective components and fastening parts must be made of materials with certain stiffness, thickness and mass. Conventional solar concentrators for large scale solar systems appear bulky, heavy and expensive. For instance, the trough concentrators used to construct large scale solar thermal power plant are built of glass or aluminum mirrors which are assembled and fastened with steel or aluminum structure. The metal support structure occupies more than 40% total cost of the trough solar concentrator. For maintaining the precision shape of the reflector, the support and fasten structure becomes bulky and heavy. In addition, in the open systems, the reflective surface of the reflector structure is directly exposed to the outdoor condition and lacks protection from dust and other contaminations.

Most solar concentrators are effective only with directly incident solar radiation, so most solar concentrators are driven by a power system and a control system to track the sun and maintain direct solar incidence. When the solar concentrator is heavy, it adds significant loads to the tracking system and makes it complicated and expensive.

Hybrid solar thermal and photovoltaic conversion is very well approved an effective approach in improving conversion efficiency of solar systems. The total conversion efficiency of flat plate hybrid solar thermal and photovoltaic system is approved to be about 72%. However, the heat harvested in flat plate system is a low temperature low quality energy source which is not fit for advanced applications such as thermal power generation, cooling and heating. On the other hand, the flat plate photovoltaic panel is too expensive and too non-efficient to be widely adopted. Concentrating hybrid solar thermal and photovoltaic conversion appears a promising approach toward high efficiency, low cost and high grad power generation. However, heretofore there is no any satisfied design paradigm to integrate photovoltaic system into the concentrating solar thermal systems.

In general, for widely spread adoption of solar application system, it is necessary to develop a solar collector that incorporates high efficiency and low cost concentrator and high efficiency hybrid solar thermal and photovoltaic converter into a concentrating hybrid solar thermal and photovoltaic collector kit to generate high quality electric power and high temperature heat in the same time.

### OBJECTS AND ADVANTAGES

This disclosure provides a configuration of concentrating hybrid solar thermal and photovoltaic collector and its components including high efficiency low cost concentrator and high efficiency hybrid solar thermal and photovoltaic converter. The solar concentrator adopts close structure to get rid of bulky, heavy and expensive support and fasten structure, which is necessary to retain the shape of reflector and against wind load, of open type concentrator. This unique structure makes it possible to construct solar concentrator with thin and light materials but still retain strong mechanical strength to against wind load and maintains reflector shape. This unique structure of this concentrator makes it cost effective in the condition of the same performance as open concentrator. As the receiver of the concentrating system, the high efficiency hybrid thermal and photovoltaic converter is made of vacuum tube, absorber and thin film solar cell, where the thin film solar cell is coated on the absorber surface and the absorber is encapsulated in the vacuum tube to form a photovoltaic module. The absorber is a fin pipe or directly a pipe where heat transfer fluids are pumped through. When the concentrated sunlight incidents on the thin film solar cell, portion of the light is converted into electricity and the rest is converted into heat which is carried out by fluid flowing in the pipes. The vacuum tube photovoltaic module saves all packing of conventional solar cells and ensures high temperature, high quality heat harvesting. In the configuration of the concentrating hybrid solar thermal and photovoltaic collector kit, the vacuum tube receiver is mounted on the focal line of the close structure concentrator. The vacuum tube isolates the hybrid solar thermal and photovoltaic receiver from the close structure concentrator, therefore eliminates the interaction between high temperature receiver and concentrator.

The concentrating hybrid solar thermal and photovoltaic collector kit of this disclosure not only shows great potential in significantly lowering the cost and raising conversion efficiency of solar system, but also shows great capacity in raising the quality of output energy. Low cost high temperature heat generation will not only make solar powered heating and cooling affordable, but also makes solar thermal power generation cost effective. This in conjunction with thermal storage will help to eliminate the intermittence of solar systems.

### SUMMARY

In summary, this disclosure is to create a solar collector kit that significantly reduce the cost, substantially raise the efficiency of solar systems. This solar collector apparatus is not only able to generate electricity and heat in the mean time, but also able to generate high temperature heat that makes solar powered heating, cooling and thermal electric power generating feasible. The feature of this apparatus will greatly promote the widely spread adoption of solar systems.

In one embodiment, the concentrating hybrid solar thermal and photovoltaic collector comprises a concentrator and a receiver. The concentrator has a close structure that enables the adoption of thin and light materials and gets free of bulky, heavy and expensive support and fastening of conventional concentrator. The unique structure makes the concentrator light-weight and forms a natural protection to its reflective surface. The receiver is a vacuum tube with absorber coated with thin film solar cell. The thermal absorber coated with thin film solar cell is mounted in vacuum tube to form hybrid solar thermal and photovoltaic module. The hybrid solar thermal and photovoltaic module is mounted in the close structure concentrator on the focal line of its reflector.

It is to be understood that both the foregoing general description and the following detailed description are exemplary and explanatory only and are not restrictive of the invention, as claimed.

### BRIEF DESCRIPTION OF THE DRAWINGS

The accompanying drawings, which are incorporated in and constitute a part of this specification, illustrate several embodiments of the invention and together with the description, serve to explain the principles of the invention.

FIG. 1 is the assembly of the concentrating hybrid solar thermal and photovoltaic collector. The collector comprises a close structure concentrator and a vacuum tube solar thermal and photovoltaic module. Where the module is mounted on the focal line of the close structure concentrator.

FIG. 2 is a cross section of FIG. 1. Where the close structure concentrator is constructed with the upper clear cover 10, the lower parabolic trough 15 and the reflective surface 18; the thermal and photovoltaic module is mounted on the focal line of the lower parabolic trough.

FIG. 3 is the enlarged cross section of a component of FIG. 2. The vacuum tube solar thermal and photovoltaic module comprises a vacuum tube 20, a fin pipe 25 serving as absorber, and the thin film solar cell 28, which is coated on the lower surface of the absorber.

FIG. 4 is the cross section of FIG. 1 along the length direction. Where the concentrator is closed with 2 ends and the thermal and photovoltaic module is also sealed at the 2 ends.

FIG. 5 shows the reflector's structure and the light path of incident light and reflected light of conventional open concentrator.

FIG. 6 shows the reflector's structure and the light path of incident light and reflected light of our new close structure concentrator.

FIG. 7 is the cross section of alternative vacuum tube hybrid solar thermal and photovoltaic converter, where the fin pipe is replaced by just a round tube and the thin film solar cell is coated on the lower half exterior surface of the pipe. The pipe can be either metal or glass, both of them are encapsulated into glass vacuum tube.

### DETAILED DESCRIPTION

Reference will now be made in detail to the present exemplary embodiment, example of which is illustrated in the accompanying drawings. Wherever possible, the same reference numbers will be used throughout the drawings to refer to the same or like parts.

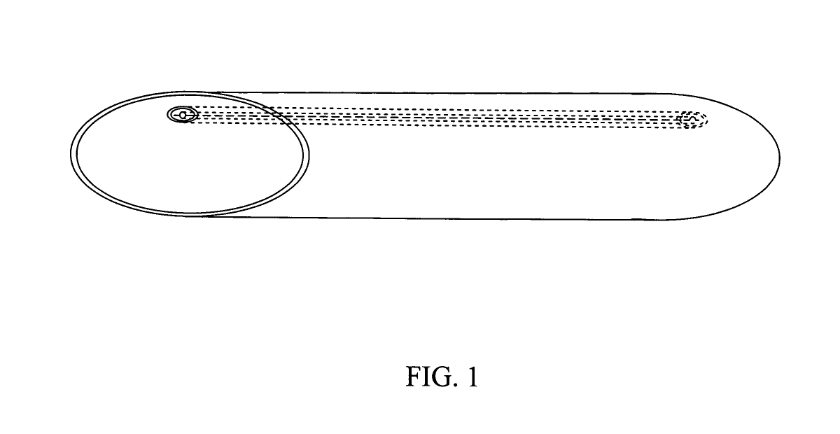

Referring to FIG. 1, the concentrating hybrid solar thermal and photovoltaic collector is consists of 2 components, a close structure concentrator and a receiver. In the configuration of this collector, the receiver is enclosed into the close structure concentrator body so as to be protected against any contamination. The close structure of the concentrator makes it possible construct the concentrator with thin and light weight material but still retain its mechanical strength to against wind load. The close structure get rid of bulky, heavy and expensive support and fasten materials of conventional open concentrator and therefore makes it cheap and light.

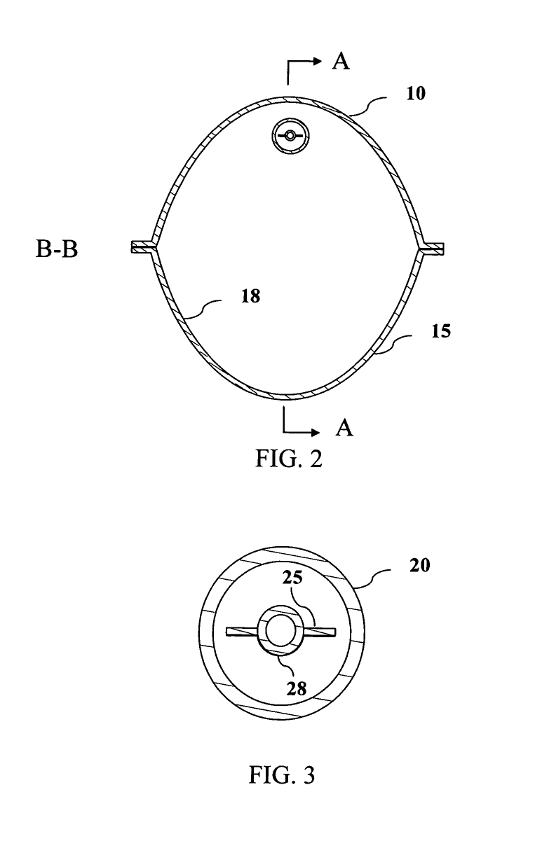

Referring to FIG. 2, the upper transparent cover 10 and the lower parabolic trough 15 are connected together to form the close structure body of the concentrator, and the reflective film 18 is coated on the inner surface of the parabolic trough. In the collector assembly, the receiver is mounted on the focal line of the lower parabolic trough 15. Where it forms a vacuum space to isolate the absorber from the rest space of the concentrator so as to terminate the interaction between the absorber and the concentrator body.

Referring to FIG. 3, the receiver is a vacuum tube solar thermal and photovoltaic module which comprises a fin pipe absorber 25, a vacuum tube 20 and a thin film solar cell 28. In the configuration of the receiver, the fin pipe 25 coated with thin film solar cell 28 is encapsulated in the vacuum tube which is sealed on the both ends. When the concentrated sunlight penetrates through the vacuum tube and incidents on the thin film solar cell, portion of the light is converted into electricity directly, and the rest part becomes into heat for the fin pipe to collect and transport out via fluid flowing. This structure of the solar thermal and photovoltaic module ensures the high efficiency thermal conversion and saves the packing of the thin film solar cell. This structure can not only generate electric power and heat in the mean time, but also generate high temperature thermal energy. The concentrating hybrid solar thermal and photovoltaic collector is not only able to increase the total conversion efficiency of solar systems, but also able to make solar powered cooling, heating and thermal power generating practical and economical.

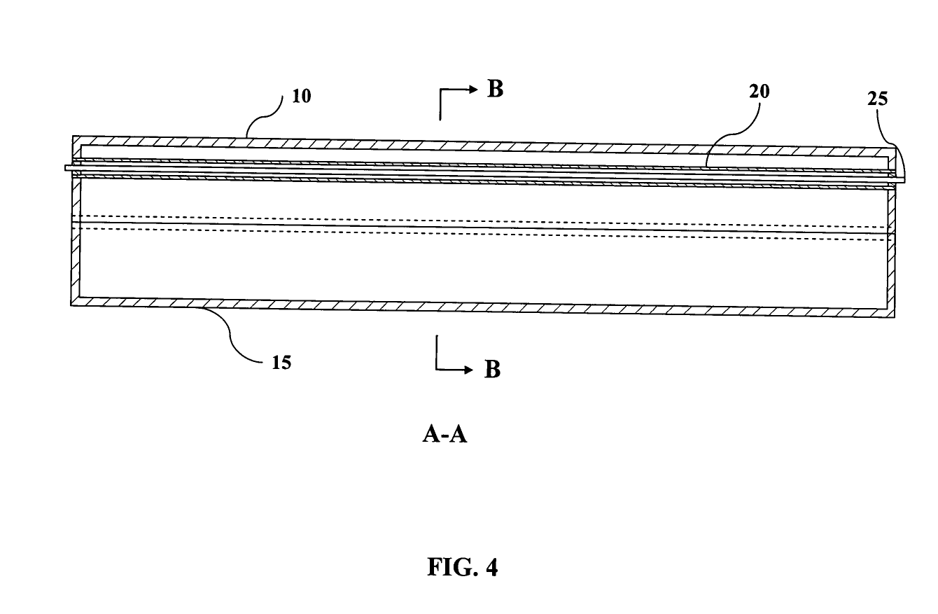

FIG. 4 shows the cross section of the collector along the length direction. The concentrator can be enclosed in 2 alternative ways, one is to mold the upper transparent cover and the lower parabolic trough into concave shape and connect them together, the other is to shape sheet materials into curved upper transparent cover and the lower parabolic trough and connect them together to form a tube. Then enclose the tube with 2 ends.

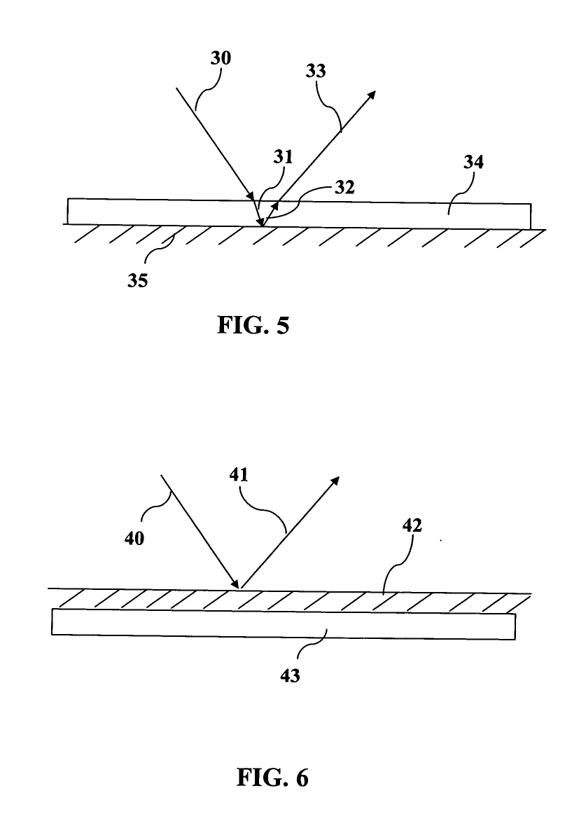

Comparing with conventional open concentrator, the close structure concentrator encapsulates the reflective surface into the close concentrator body. This not only provides a natural protection to the reflector, but also reduces the optical loss of the system. Referencing FIG. 5, in conventional open concentrator, the reflector 35 is coated beneath the transparent sheet 34 and the incident light 30 penetrates the sheet to form path 31 that is reflected by the reflector 35 to form path 32 and back path 33. Here the incident light makes a round trip before it is reflected to receiver. Referencing FIG. 6, in the close structure concentrator of this disclosure, the reflector 42 is coated on the upper surface of the transparent sheet 43 and the incident light 40 is directly reflected back to form path 41. Considering the extra transparent cover, the close structure concentrator saves one trip of light in the transparent sheet.

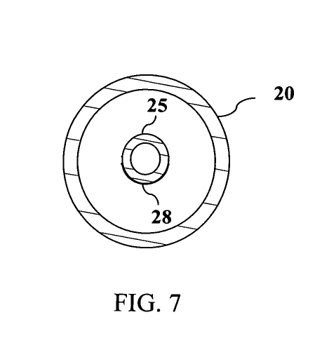

Referencing the FIG. 7, the vacuum tube hybrid solar thermal and photovoltaic has another version, where the fin pipe is replaced by a round pipe that can be metal or glass so as to apply this structure to all glass vacuum tube and metal and glass vacuum tube.

I claim:

1. A solar collector, comprising:
a close structure solar concentrator;
a receiver comprising a vacuum tube, a fin pipe, and a thin film solar cell, the receiver mounted on the focal line of the solar concentrator;
wherein the thin film solar cell is coated on the lower surface of the fin pipe and the fin pipe is encapsulated into the vacuum tube; and
Wherein the receiver forms a vacuum space that ensures high efficiency thermal conversion and terminates the heat transfer between the receiver and the concentrator.

2. The solar concentrator of claim 1, one embodiment comprising an upper transparent cover, a lower parabolic trough and a reflective layer, wherein the concentrator is constructed with an upper concave transparent cover and a concave lower parabolic trough that are connected to form a close structure, the upper concave transparent cover and the lower concave parabolic trough are molded into unitary bodies;
Wherein the close structure of the concentrator enables it to be constructed with thin and light-weight materials but retain strong mechanical strength to against wind load, this close structure is free of bulky, heavy and expensive support and fastening materials.

3. The solar concentrator of claim 2, wherein the reflective layer is located on the inner surface of the lower concave parabolic trough, the incident sunlight penetrates through the upper concave transparent cover and is reflected by the reflective layer directly to the receiver.

4. The solar concentrator of claim 1, the second embodiment comprising a curved upper transparent cover, a curved lower parabolic trough, two ends and a reflective layer, wherein the curved upper transparent cover and the curved lower parabolic trough are connected to form a tube, and the tube is enclosed with the two ends to complete the close structure concentrator.

5. The solar concentrator of claim 4, wherein the reflective layer is located on the inner surface of the curved lower parabolic trough, the incident sunlight penetrates through the upper curved transparent cover and is reflected by the reflective layer directly to the receiver.

6. The solar concentrator of claim 1, wherein the second embodiment of the receiver comprising a vacuum tube, a pipe and a thin film solar cell, the thin film solar cell is coated on the lower half exterior surface of the pipe, and the pipe is encapsulated in the vacuum tube.

7. The receiver of claim 6, wherein the pipe can be either metal or glass, both of them are encapsulated into glass vacuum tube.
